(19) United States
(12) Patent Application Publication
(10) Pub. No.: US 2020/0402883 A1
(43) Pub. Date: Dec. 24, 2020

(54) SEMICONDUCTOR PACKAGES HAVING HEAT SPREADER

(71) Applicant: Samsung Electronics Co., Ltd., Suwon-si (KR)

(72) Inventors: Younglyong Kim, Anyang-si (KR); Aenee Jang, Seou (KR)

(73) Assignee: Samsung Electronics Co., Ltd., Suwon-si (KR)

(21) Appl. No.: 16/701,903

(22) Filed: Dec. 3, 2019

(30) Foreign Application Priority Data
Jun. 18, 2019 (KR) 10-2019-0072360

(51) Int. Cl. H01L 23/367; H01L 25/18; H01L 23/31; H01L 23/00

(52) U.S. Cl. CPC H01L 23/367; H01L 23/49816; H01L 23/3107; H01L 24/16; H01L 24/48; H01L 24/32; H01L 24/33; H01L 24/73; H01L 2224/16227; H01L 2224/32245; H01L 2224/32145; H01L 2224/33181; H01L 2224/48227; H01L 2224/48105; H01L 2224/73215; H01L 2224/73253; H01L 2224/73265; H01L 25/18

(57) ABSTRACT

A semiconductor package includes a lower semiconductor chip disposed on a substrate, at least one upper semiconductor chip disposed on the lower semiconductor chip, a heat spreader bonded on the lower semiconductor chip and the at least one upper semiconductor chip, and an encapsulant surrounding side surfaces of the heat spreader. A lower surface of the heat spreader includes a first protrusion and a non-protruding portion, the first protrusion is in contact with an upper surface of the lower semiconductor chip, and the non-protruding portion is in contact with an upper surface of the at least one upper semiconductor chip.

### CROSS-REFERENCE TO RELATED APPLICATION

This application claims from Korean Patent Application No. 10-2019-0072360, filed on Jun. 18, 2019, the disclosure of which is incorporated herein by reference in its entirety.

### BACKGROUND

### 1. Field

Devices consistent with example embodiments relate to a semiconductor packages having a heat spreader.

### 2. Description of Related Art

With the trend toward downsizing of semiconductor devices, techniques for mounting semiconductor chips having respective functions into a single semiconductor package are in demand. Since such a high-density semiconductor package may generate a relatively large amount of heat inside, a heat dissipation system may be utilized for stability and reliability of the device.

### SUMMARY

Example embodiments of inventive concepts are directed to providing a semiconductor package including a heat spreader with improved heat dissipation characteristics.

According to some example embodiments, a semiconductor package may include a lower semiconductor chip on a substrate; at least one upper semiconductor chip on the lower semiconductor chip; a heat spreader bonded on the lower semiconductor chip and the at least one upper semiconductor chip, the heat spreader including a first protrusion and a non-protruding portion on a lower surface thereof, the first protrusion being in contact with an upper surface of the lower semiconductor chip and the non-protruding portion being in contact with an upper surface of the at least one upper semiconductor chip; and an encapsulant surrounding at least the substrate, the lower semiconductor chip, the at least one upper semiconductor chip, and side surfaces of the heat spreader.

According to some example embodiments, a semiconductor package may include a first lower semiconductor chip and a second lower semiconductor chip in parallel on a substrate; at least one first upper semiconductor chip on the first lower semiconductor chip; at least one second upper semiconductor chip on the second lower semiconductor chip; a first heat spreader bonded on the first lower semiconductor chip and the at least one first upper semiconductor chip, the first heat spreader including a protrusion and a non-protruding portion on a lower surface thereof such that the protrusion is in contact with the first lower semiconductor chip and the non-protruding portion is in contact with the at least one first upper semiconductor chip; and a encapsulant surrounding at least the substrate, the first lower semiconductor chip, the second lower semiconductor chip, the at least one first upper semiconductor chip, the at least one second upper semiconductor chip, and side surfaces of the first heat spreader.

According to some example embodiments, a semiconductor package may include a lower semiconductor chip on a substrate; at least one upper semiconductor chip on the lower semiconductor chip; a heat spreader bonded on the lower semiconductor chip and the at least one upper semiconductor chip, the heat spreader including a protrusion and a non-protruding portion on a lower surface thereof such that the non-protruding portion is in contact with an upper surface of the at least one upper semiconductor chip; heat transfer materials connecting the lower semiconductor chip and the at least one upper semiconductor chip to the heat spreader; and a encapsulant surrounding the substrate, the lower semiconductor chip, the at least one upper semiconductor chip, and side surfaces of the heat spreader such that an upper surface of the heat spreader is partially exposed

### BRIEF DESCRIPTION OF THE DRAWINGS

The above and other objects, features, and advantages of example embodiments of the inventive concepts will become more apparent to those of ordinary skill in the art by describing some example embodiments thereof in detail with reference to the accompanying drawings, in which:

FIG. 1 is a plan view of a semiconductor package according to an example embodiment of inventive concepts.

FIG. 2 is a vertical cross-sectional view of the semiconductor package of FIG. 1, taken along line I-I′.

FIG. 3 is a vertical cross-sectional view of the semiconductor package of FIG. 1, taken along line II-II′.

FIG. 4 to FIG. 17 are plan views and vertical cross-sectional views of the semiconductor package according to an example embodiment of inventive concepts.

FIG. 18 to FIG. 22 are vertical cross-sectional views illustrating in a process order of a method of manufacturing a semiconductor package according to an example embodiment of inventive concepts.

FIG. 23 is a vertical cross-sectional view of a semiconductor package according to an example embodiment of inventive concepts.

### DETAILED DESCRIPTION

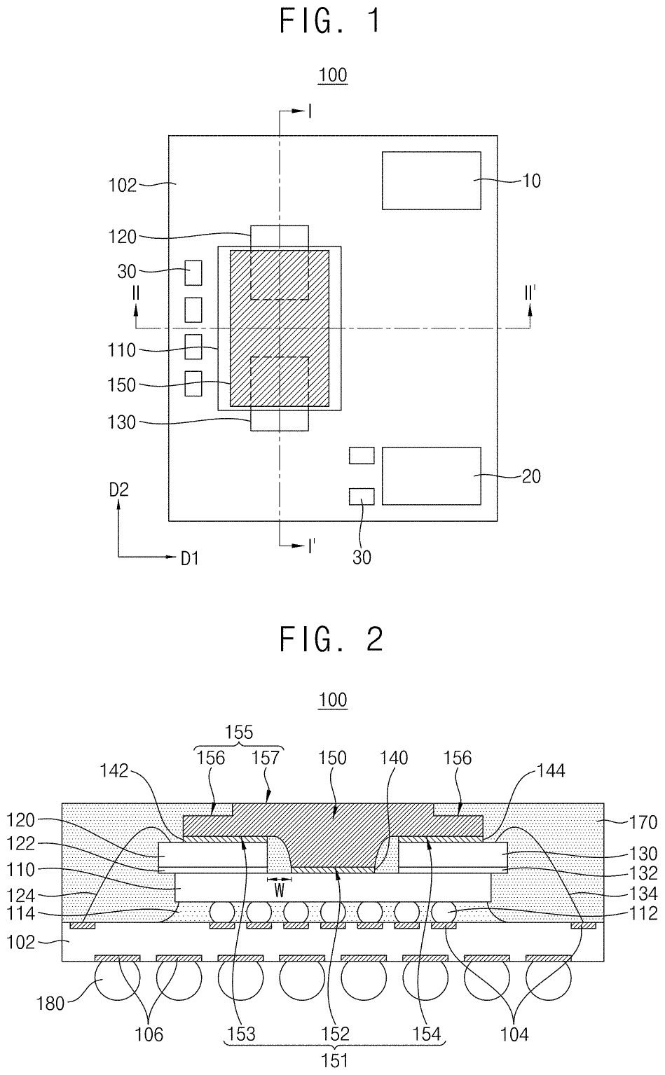

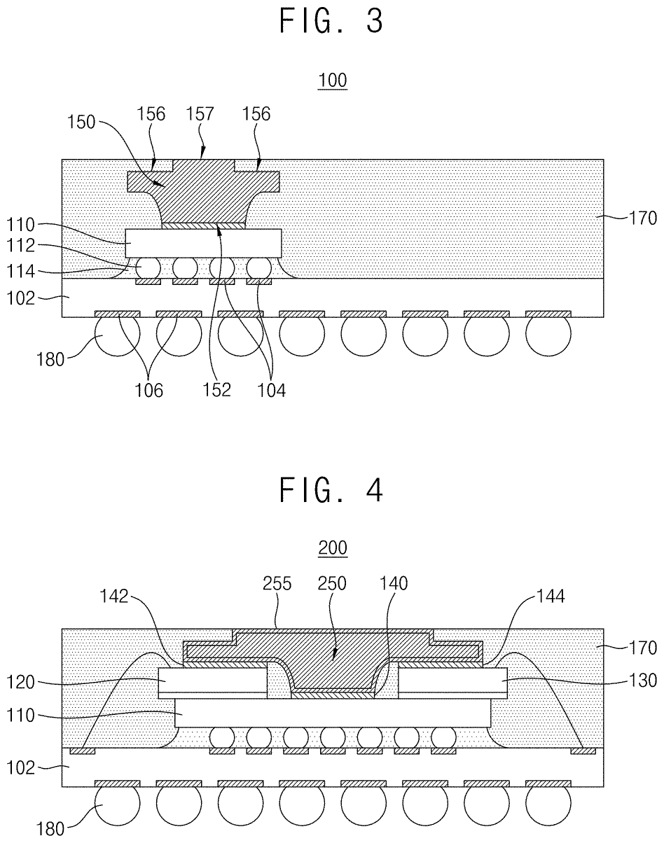

FIG. 1 is a plan view of a semiconductor package according to an example embodiment of inventive concepts. FIG. 2 is a vertical cross-sectional view of the semiconductor package of FIG. 1, taken along line I-I′. FIG. 3 is a vertical cross-sectional view of the semiconductor package of FIG. 1, taken along line II-Ir.

Referring to FIGS. 1 to 3, a semiconductor package 100 includes a substrate 102, active devices 10 and 20, a passive device 30, a lower semiconductor chip 110, a first upper semiconductor chip 120, a second upper semiconductor chip 130, an encapsulant 170, and an external connection terminal 180. The semiconductor package 100 may further include a lower heat transfer material 140, a first upper heat transfer material 142, a second upper heat transfer material 144, and a heat spreader 150.

The semiconductor package 100 according to an example embodiment of inventive concepts may be a system-in-package (SiP) system that includes the active devices 10, 20 and the passive device 30 such as a resistor or inductor.

The substrate 102 may include a plurality of upper pads 104 and a plurality of lower pads 106. The substrate 102 may include wiring (not shown) having a multilayer structure connecting the plurality of upper pads 104 and the plurality of lower pads 106 therein. The substrate 102 may electrically connect the lower semiconductor chip 110, the first upper semiconductor chip 120, and the second upper semiconductor chip 130 to the external connection terminal 180.

The active devices 10 and 20, the passive device 30 and the lower semiconductor chip 110 may be disposed on the substrate 102. The active devices 10 and 20 may include a power management integrated circuit (PMIC), a Radio Frequency Integrated Circuit (RF IC) chip, and the like. The passive device 30 may include a resistor, a capacitor, or an inductor.

The lower semiconductor chip 110 may be stacked on the substrate 102. In an example embodiment, the lower semiconductor chip 110 may be mounted on the substrate 102 in a flip chip manner. The lower semiconductor chip 110 may be electrically connected to the upper pad 104 of the substrate 102 through a substrate connection terminal 112 disposed below the lower semiconductor chip 110. An underfill 114 may be disposed below the lower semiconductor chip 110 and may cover a lower surface of the lower semiconductor chip 110 and the substrate connection terminal 112. In an example embodiment, the underfill 114 may include an epoxy resin.

The first upper semiconductor chip 120 may be stacked on the lower semiconductor chip 110. A lower surface of the first upper semiconductor chip 120 may partially contact the lower semiconductor chip 110. A first adhesive 122 may be disposed below the first upper semiconductor chip 120 and may fix the first upper semiconductor chip 120 on the lower semiconductor chip 110. The first adhesive 122 may include a die attach film (DAF) or an epoxy resin. In an example embodiment, the first upper semiconductor chip 120 may be electrically connected to the substrate 102 by wire bonding. For example, the first upper semiconductor chip 120 may be electrically connected to the upper pad 104 of the substrate 102 via a first bonding wire 124 connected to an upper surface of the first upper semiconductor chip 120.

The second upper semiconductor chip 130 may be spaced apart from the first upper semiconductor chip 120 on the lower semiconductor chip 110. The second upper semiconductor chip 130 may be laminated on the lower semiconductor chip 110 by a second adhesive 132. The second upper semiconductor chip 130 may be connected to the upper pad 104 of the substrate 102 through a second bonding wire 134.

The lower semiconductor chip 110 may include logic chips such as an application processor (AP) chip (e.g., micro process and micro controller), a CPU, a GPU, a modem, an application-specific IC (ASIC), and a field programmable gate array (FPGA). The first upper semiconductor chip 120 and the second upper semiconductor chip 130 may include a volatile memory chip such as a DRAM or a non-volatile memory chip such as a flash memory. In an example embodiment, the lower semiconductor chip 110 may include a modem chip, and the first upper semiconductor chip 120 and the second upper semiconductor chip 130 may include DRAM chips.

The lower heat transfer material 140, the first upper heat transfer material 142 and the second upper heat transfer material 144 may partially cover an upper surface of the lower semiconductor chip 110, an upper surface of the first upper semiconductor chip 120, and an upper surface of the second upper semiconductor chip 130, respectively. The lower heat transfer material 140, the first upper heat transfer material 142 and the second upper heat transfer material 144 may include a thermal interface material (TIM) including a polymer, a resin, or an epoxy and a filler.

The heat spreader 150 may be disposed on the lower semiconductor chip 110, the first upper semiconductor chip 120, and the second upper semiconductor chip 130. A lower surface 151 of the heat spreader 150 may include a protrusion 152, a first non-protruding portion 153 and a second non-protruding portion 154. The protrusion 152 may have a downward protruding shape and may be disposed between the first non-protruding portion 153 and the second non-protruding portion 154. The first non-protruding portion 153 and the second non-protruding portion 154 may be located at different levels from the protrusion 152. A side surface of the protrusion 152 connected to the first non-protruding portion 153 or the second non-protruding portion 154 may be rounded concavely. Since, the side surface of the protrusion 152 is a rounded surface rather than a vertical surface, the first upper semiconductor chip 120 and the second semiconductor chip 130 may be spaced apart from the protrusion 152 by a desired (or, alternatively, a predetermined) distance W, so that the first upper semiconductor chip 120, the second upper semiconductor chip 130, and the heat spreader 150 may contact each other on a flat surface. For example, the protrusion 152, the first upper semiconductor chip 120, and the second upper semiconductor chip 130 may be spaced apart from each other by the distance W of 100 μm or more in the horizontal direction.

The protrusion 152, the first non-protruding portion 153 and the second non-protruding portion 154 may be in contact with the lower heat transfer material 140, the first upper heat transfer material 142 and the second upper heat transfer material 144, respectively. The heat spreader 150 is bonded to the lower semiconductor chip 110, the first upper semiconductor chip 120, and the second upper semiconductor chip 130 by the lower heat transfer material 140, the first upper heat transfer material 142, and the second upper semiconductor chip 130, respectively. The lower heat transfer material 140, the first upper heat transfer material 142 and the second upper heat transfer material 144 may transfer heat from the lower semiconductor chip 110, the first upper semiconductor chip 120, and second upper semiconductor chip 130 to the heat spreader 150, respectively. The first upper heat transfer material 142, the second upper heat transfer material 144, and the heat spreader 150 may be disposed so as not to contact the first bonding wire 124 and the second bonding wire 134.

An upper surface 155 of the heat spreader 150 may include a recessed portion 156 and an upper surface portion 157. The recessed portion 156 may be disposed at the edge of the upper surface 155 of the heat spreader 150 and the upper surface portion 157 may be disposed at the center portion of the upper surface 155 of the heat spreader 150. The recessed portion 156 may be disposed in a portion of an outer side of the upper surface portion 157 or may be arranged to surround the outer side of the upper surface portion 157. An upper surface of the recessed portion 156 may be located at a lower level than an upper surface of the encapsulant 170 and may be covered with the encapsulant 170. The upper surface portion 157 may be exposed without being covered by the encapsulant 170. For example, the upper surface of the upper surface portion 157 may be located at the same level as the upper surface of the encapsulant and may be co-planar with the upper surface of the encapsulant 170. The heat spreader 150 may include a material having a high thermal conductivity, for example, the heat spreader 150 may be made of Ag, Cu, Ni, Au, or a combination thereof.

Since the heat spreader 150 has a structure in contact with all of the lower semiconductor chip 110, the first upper semiconductor chip 120 and the second upper semiconductor chip 130, heat from three semiconductor chips 110, 120, and 130 may be dissipated to the outside. Generally, chips may be arranged in a stack structure in which memory chips are stacked on a logic chip, while a heat spreader may only make contact with upper chips stacked relatively higher than the logic chip. By connecting a logic chip with high heat generation to a heat spreader 150, heat dissipation characteristics may be improved. In addition, since a portion of the upper surface 155 of the heat spreader 150 is exposed, the heat from the package may be dissipated more efficiently. In addition, since the heat spreader 150 is harder than the encapsulant 170, the heat spreader 150 may inhibit (or, alternatively, prevent) and alleviate warpage of the semiconductor package 100. In FIG. 1, the active devices 10 and 20 are not connected to the heat spreader 150, but are not limited thereto. In an example embodiment, the heat spreader 150 may also be placed on the active devices 10, 20.

The encapsulant 170 may surround the substrate 102, the lower semiconductor chip 110, the first upper semiconductor chip 120, the second upper semiconductor chip 130, and the heat spreader 150. The encapsulant 170 may cover side surfaces and the lower surface 151 of the heat spreader 150. The encapsulant 170 may cover the recessed portion 156 of the upper surface 155 of the heat spreader 150 and may inhibit (or, alternatively, prevent) the heat spreader 150 from being separated from the semiconductor package 100. In an example embodiment, the encapsulant 170 may include an epoxy molding compound (EMC). A height from an upper surface of the substrate 102 to the upper surface of the encapsulant 170 may be approximately 400 μm.

FIG. 4 to FIG. 17 are plan views and vertical cross-sectional views of the semiconductor package according to an example embodiment of inventive concepts.

Referring to FIG. 4, a semiconductor package 200 may include an anti-oxidation film 255 coated on a surface of a heat spreader 250. The anti-oxidation film 255 may be formed on the surface of the heat spreader 250 by a plating process. The anti-oxidation film 255 may inhibit (or, alternatively, prevent) oxidation of the exposed heat spreader 250. The anti-oxidation film 255 may include Ni, Au, Pd, Ag, or the like. In FIG. 4, the anti-oxidation film 255 has a single layer structure, but is not limited thereto. In an example embodiment, the anti-oxidation film 255 may have a structure of two or more layers.

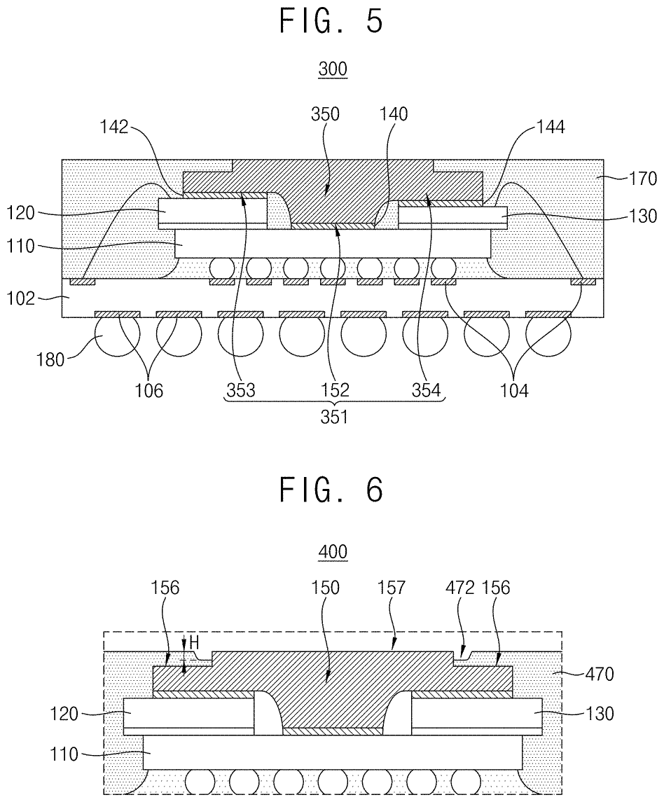

Referring to FIG. 5, a semiconductor package 300 may include a heat spreader 350 contacting the lower semiconductor chip 110, the first upper semiconductor chip 120, and the second upper semiconductor chip 130. A lower surface 351 of the heat spreader 350 may include the protrusion 152, a first non-protruding portion 353 and a second non-protruding portion 354. In an example embodiment, the thickness of the second upper semiconductor chip 130 may be smaller than the thickness of the first upper semiconductor chip 120. The first non-protruding portion 353 may be located at a higher level than the second non-protruding portion 354.

FIG. 6 is a partial enlarged view of a semiconductor package according to an example embodiment of inventive concepts.

Referring to FIG. 6, a semiconductor package 400 includes a encapsulant 470 covering the lower semiconductor chip 110, the first upper semiconductor chip 120, the second upper semiconductor chip 130, and the heat spreader 150. The encapsulant 470 may include a groove 472 on an upper surface thereof. The groove 472 may be disposed adjacent to the upper surface 155 of the heat spreader 150 and may be disposed along the outer circumference of the upper surface portion 157 of the heat spreader 150, for example. Side surfaces of the upper surface portion 157 of the heat spreader 150 may be partially exposed. The recessed portion 156 is covered by the encapsulant 470 and may not be exposed. The groove 472 may be formed in the space where the release film (not shown) is pressed when the encapsulant 470 is formed. The distance from a lower end of the groove 472 to an upper surface of the encapsulant 470 may be 2 μm to 15 μm. In an example embodiment, the distance from the lower end of the groove 472 to the upper surface of the encapsulant 470 is 2 μm to 3 μm.

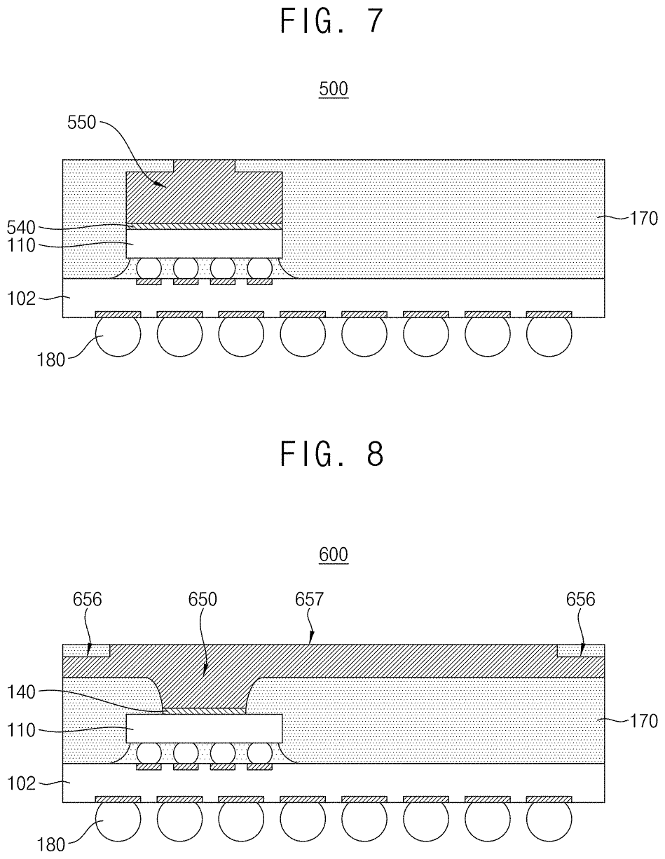

FIG. 7 is a vertical cross-sectional view of a semiconductor package according to an example embodiment of inventive concepts.

Referring to FIG. 7, a semiconductor package 500 may include a heat transfer material 540 disposed on the lower semiconductor chip 110 and a heat spreader 550 disposed on the heat transfer material 540. Horizontal widths of the heat transfer material 540 and the heat spreader 550 may be the same as a horizontal width of the lower semiconductor chip 110. For example, the horizontal widths along the second direction D2 of the heat transfer material 540 and the heat spreader 550 may be the same as the width along the second direction D2 of the lower semiconductor chip 110. The semiconductor package 500 may more efficiently dissipate heat because the heat transfer material 540 and the heat spreader 550 come into wide contact with the upper surface of the lower semiconductor chip 110. In an example embodiment, the horizontal width of the heat spreader 550 may be greater than the horizontal width of the lower semiconductor chip 110.

FIG. 8 is a vertical cross-sectional view of a semiconductor package according to an example embodiment of inventive concepts.

Referring to FIG. 8, a semiconductor package 600 may include a heat spreader 650 stacked on the lower semiconductor chip 110. The heat spreader 650 may extend in the horizontal direction. For example, a horizontal width of a recessed portion 656 of the heat spreader 650 may be greater than the horizontal width of the lower semiconductor chip 110. In an example embodiment, side surfaces of the heat spreader 650 in the second direction D2 may be vertically aligned with side surfaces of the encapsulant 170. For example, the maximum width of the heat spreader 650 along the second direction D2 may be equal to the width of the substrate 102 along the second direction D2. As shown in FIG. 8, since the semiconductor package 600 includes the heat spreader 650 having a wide upper surface portion 657, the heat inside the semiconductor package 600 may be dissipated more efficiently.

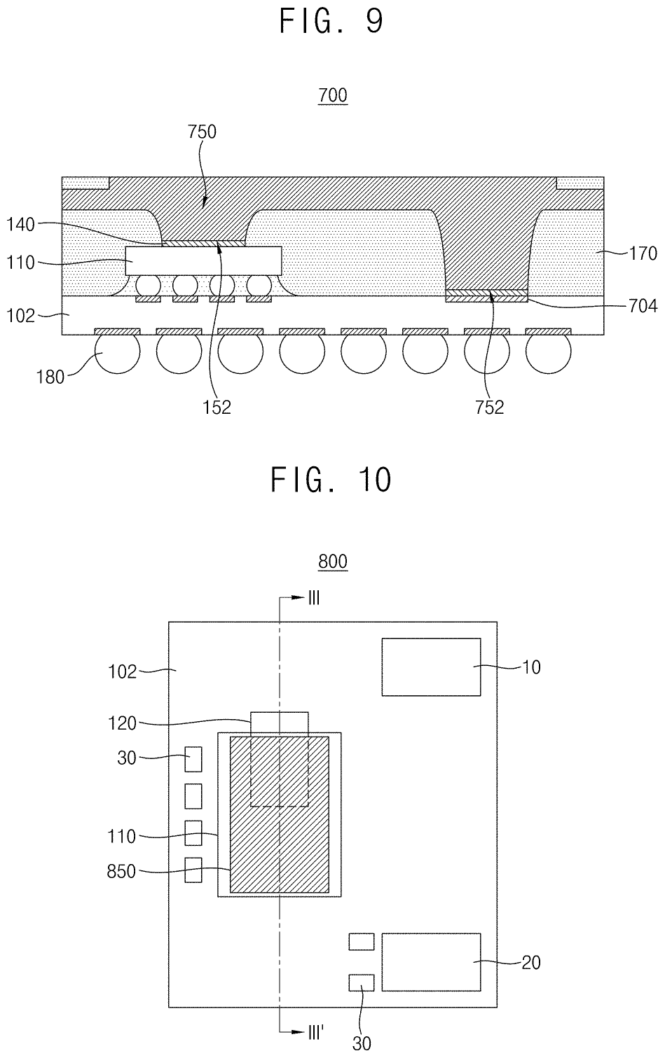

FIG. 9 is a vertical cross-sectional view of a semiconductor package according to an example embodiment of inventive concepts.

Referring to FIG. 9, a semiconductor package 700 may include the lower heat transfer material 140 disposed on the lower semiconductor chip 110 and a heat spreader 750 disposed on the lower heat transfer material 140. The heat spreader 750 may include the protrusion 152 and a protrusion 752. The protrusion 752 protrudes further downward than the protrusion 152 and may contact the upper surface of the substrate 102. In an example embodiment, the heat spreader 750 may be connected to a upper pad 704 disposed on the substrate 102 via the lower heat transfer material 140. The upper pad 704 may be a dummy pad that is not electrically connected to the upper pad 104 and the lower pad 106. As shown in FIG. 9, since the heat spreader 750 contacts the upper surface of the substrate 102, the heat of the substrate 102 as well as the lower semiconductor chip 110 may be dissipated to the outside of the semiconductor package 700.

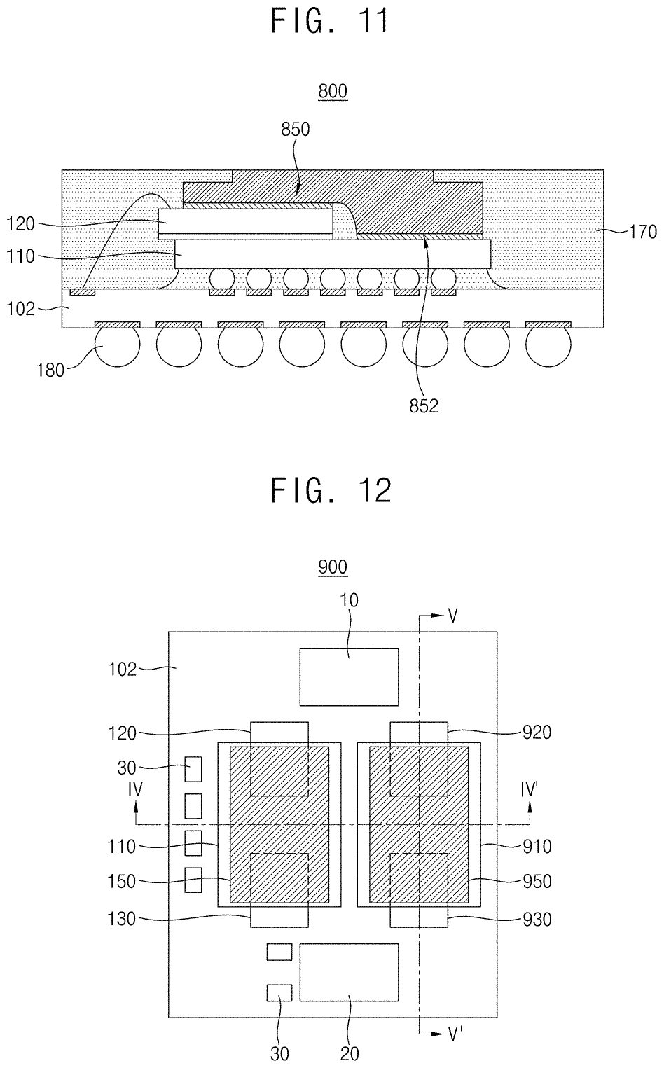

FIG. 10 is a plan view of a semiconductor package according to an example embodiment of inventive concepts. FIG. 11 is a vertical cross-sectional view of the semiconductor package of FIG. 10 taken along line III-III′.

Referring to FIGS. 10 and 11, a semiconductor package 800 may include the lower semiconductor chip 110 and a heat spreader 850 stacked on the first upper semiconductor chip 120. One first upper semiconductor chip 120 may be disposed on the lower semiconductor chip 110. The lower semiconductor chip 110 may include a logic chip, and the first upper semiconductor chip 120 may include a memory chip. In an example embodiment, the lower semiconductor chip 110 may be an AI chip, and the first upper semiconductor chip 120 may be a DRAM chip. The heat spreader 850 may include a protrusion 852. The protrusion 852 may contact the lower semiconductor chip 110.

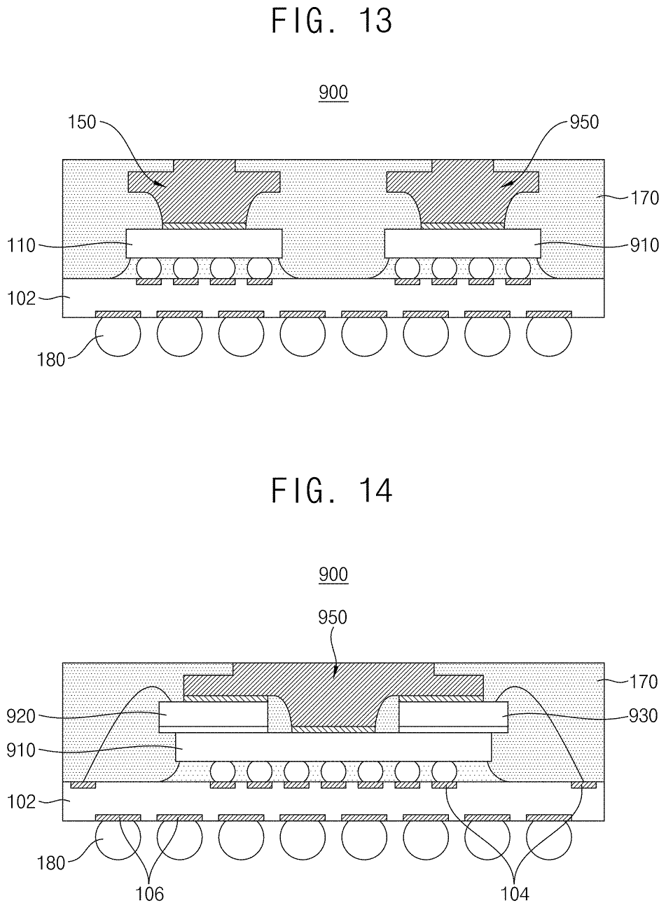

FIG. 12 is a plan view of a semiconductor package according to an example embodiment of inventive concepts. FIG. 13 is a vertical cross-sectional view of the semiconductor package of FIG. 12 taken along line IV-IV′. FIG. 14 is a vertical cross-sectional view of the semiconductor package of FIG. 12 taken along line V-V′.

Referring to FIGS. 12 to 14, a semiconductor package 900 may include the first lower semiconductor chip 110 and a second lower semiconductor chip 910 on a substrate 102. The first upper semiconductor chip 120 and the second upper semiconductor chip 130 may be disposed on the first lower semiconductor chip 110 and a third upper semiconductor chip 920 and a fourth upper semiconductor chip 930 are disposed on the second lower semiconductor chip 910. The first lower semiconductor chip 110 and the second lower semiconductor chip 910 may dissipate heat through different heat transfer paths. The first heat spreader 150 may be stacked on the first lower semiconductor chip 110, the first upper semiconductor chip 120 and the second upper semiconductor chip 130 and a second heat spreader 950 may be stacked on the second lower semiconductor chip 910, the third upper semiconductor chip 920, and the fourth upper semiconductor chip 930. The heat spreader 150 and the second heat spreader 950 may be spaced apart from each other and may not be connected.

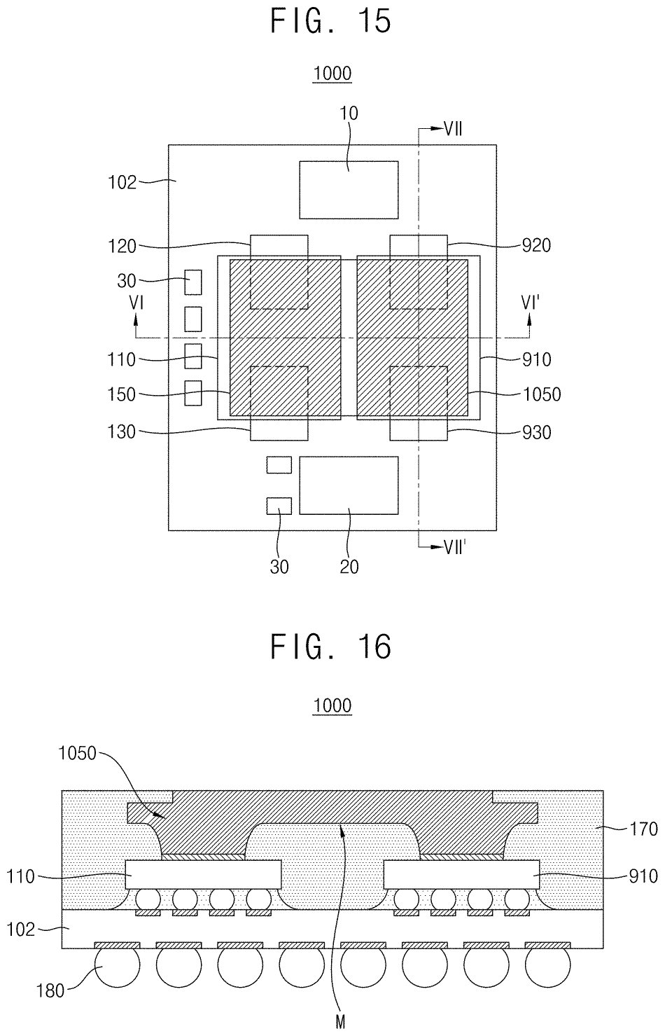

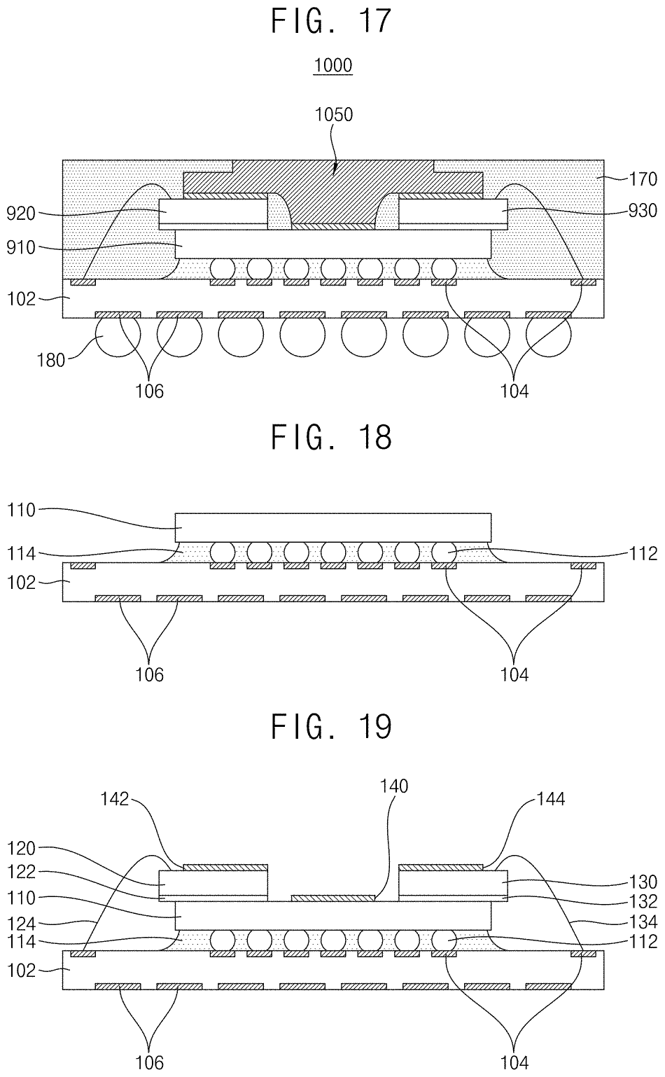

FIG. 15 is a plan view of a semiconductor package according to package according to an example embodiment of inventive concepts. FIG. 16 is a vertical cross-sectional view of the semiconductor package of FIG. 15 taken along the line VI-VI′. FIG. 17 is a vertical cross-sectional view of the semiconductor package of FIG. 15 taken along the line VII-VII

Referring to FIGS. 15 to 17, a semiconductor package 1000 includes a unified heat spreader 1050 stacked on the first lower semiconductor chip 110 and the second lower semiconductor chip 910 on a substrate 102. The unified heat spreader 1050 may also be stacked on the first upper semiconductor chip 120, the second upper semiconductor chip 130, the third upper semiconductor chip 920, and the fourth upper semiconductor chip 930. In an example embodiment, the unified heat spreader 1050 may include an intermediate non-protruding portion M between the first lower semiconductor chip 110 and the second lower semiconductor chip 910. In an example embodiment, the unified heat spreader 1050 may be connected to other heat dissipation elements in the semiconductor package 1000.

FIG. 18 to FIG. 22 are vertical cross-sectional views illustrating in a process order of a method of manufacturing a semiconductor package according to an example embodiment of inventive concepts.

Referring to FIG. 18, a lower semiconductor chip 110 may be mounted on a substrate 102. The substrate 102 includes a plurality of upper pads 104 on the upper surface thereof and a plurality of lower pads 106 on the lower surface thereof. The substrate 102 may include wiring (not shown) having a multilayer structure connecting a plurality of upper pads 104 and lower pads 106 therein. The upper pad 104 and the lower pad 106 may include metals such as Al, Ti, Cr, Fe, Co, Ni, Cu, Zn, Pd, Pt, Au and Ag.

The lower semiconductor chip 110 may be mounted on the substrate 102 in a flip chip manner. The lower semiconductor chip 110 may be electrically connected to the upper pad 104 of the substrate 102 by a substrate connection terminal 112 disposed below the lower semiconductor chip 110. The substrate connection terminal 112 may be a C4 bump. The substrate connection terminal 112 may be electrically connected to the lower pad 106 of the lower surface of the substrate 102 through the upper pad 104 on the upper surface of the substrate 102. A underfill 114 may be disposed below the lower semiconductor chip 110 to cover a lower surface of the lower semiconductor chip 110 and the substrate connection terminal 112. The underfill 114 may include Non Conductive Paste (NCP), Non Conductive Film (NCF), Capillary Underfill (CUF), or other insulating material. Although not shown, active devices 10 and 20 and a passive device 30 may be further disposed on the substrate 102.

Referring to FIG. 19, a first upper semiconductor chip 120 and a second upper semiconductor chip 130 may be stacked on the lower semiconductor chip 110. The first upper semiconductor chip 120 may be stacked by a first adhesive 122 and the second upper semiconductor chip 130 may be stacked by a second adhesive 132. The first adhesive 122 and the second adhesive 132 may include a DAF. The first upper semiconductor chip 120 and the second upper semiconductor chip 130 may be connected to the upper pad 104 by first bonding wires 124 and second bonding wires 134, respectively.

A lower heat transfer material 140 may be disposed on the lower semiconductor chip 110 and may be disposed between the first upper semiconductor chip 120 and the second upper semiconductor chip 130. A first upper heat transfer material 142 may be disposed on the first upper semiconductor chip 120. A second upper heat transfer material 144 may be disposed on the second upper semiconductor chip 130. The lower heat transfer material 140, the first upper heat transfer material 142, and the second upper heat transfer material 144 may be provided by a dispensing method. The first upper heat transfer material 142 and the second upper heat transfer material 144 may not be in contact with the first bonding wire 124 and the second bonding wire 134, respectively.

The lower heat transfer material 140, the first upper heat transfer material 142 and the second upper heat transfer material 144 may include a thermal interface material (TIM) comprising a polymer, a resin, or an epoxy and a filler. The filler may include a dielectric filler such as aluminum oxide, magnesium oxide, aluminum nitride, boron nitride, and diamond powder. The filler may also be a metal filler such as silver, copper, aluminum, and the like.

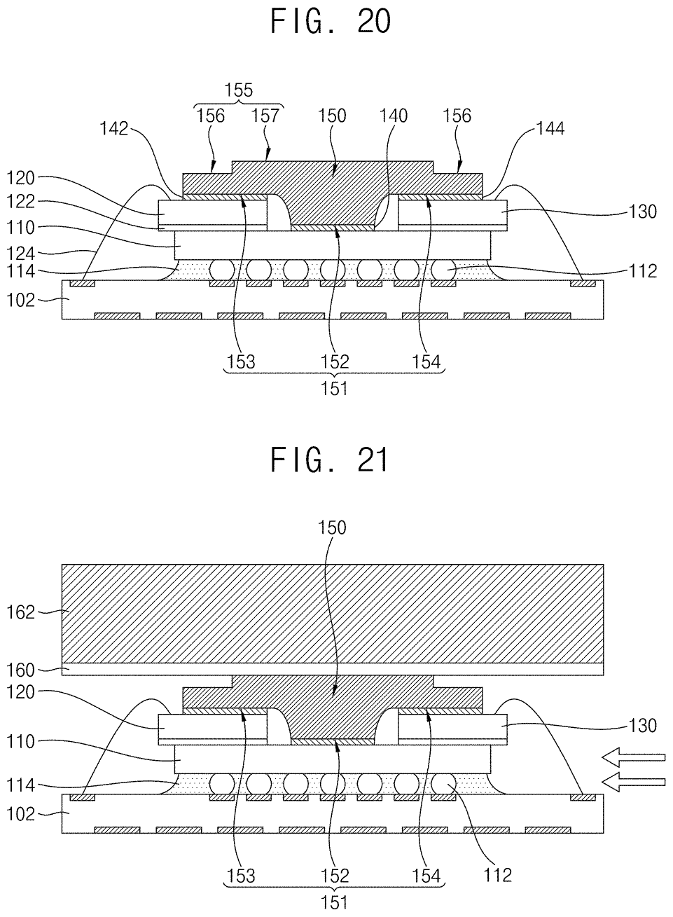

Referring to FIG. 20, a heat spreader 150 may be disposed on the lower heat transfer material 140, the first upper heat transfer material 142, and the second upper heat transfer material 144. A lower surface 151 of the heat spreader 150 may include a protrusion 152, a first non-protruding portion 153 and a second non-protruding portion 154. An upper surface 155 of the heat spreader 150 may include a recessed portion 156 and an upper surface portion 157. The heat spreader 150 may be formed by etching a metal plate. For example, the half-etching process may be performed using a mask on a part of the lower surface 151 of the heat spreader 150 to form the first non-protruding portion 153 and the second non-protruding portion 154. The recessed portion 156 may be formed by partially etching the upper surface 155 of the heat spreader 150. In the etching process, side surfaces of the protrusion 152 may not be a vertical surface. For example, the side surfaces of the protrusion 152 may be rounded concavely.

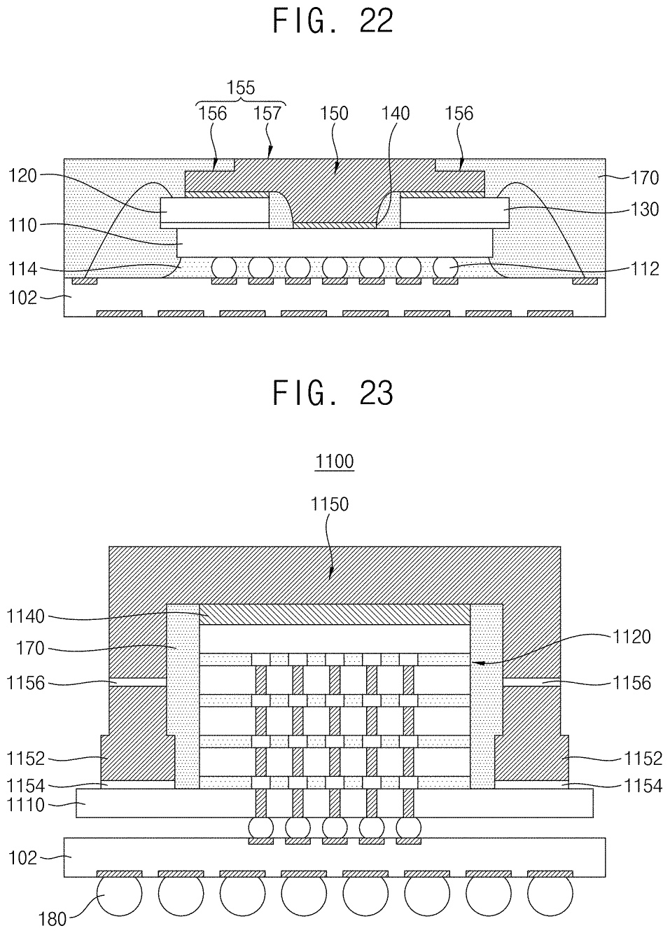

Referring to FIGS. 21 and 22, an encapsulant 170 may be formed. The encapsulant 170 may be formed by disposing the substrate 102 and the elements mounted on the substrate 102 on a mold 162 having a release film 160 attached to its surface and then injecting the molding material. FIG. 21 illustrates transfer molding, but is not limited thereto. In an example embodiment, the encapsulant 170 may be formed by a compression molding method. In an example embodiment, in the step of injecting the molding material, the release film 160 may partially cover side surfaces of the upper surface 155 of the heat spreader 150. As shown in FIG. 6, the encapsulant 170 may include a groove 472 disposed at an upper portion adjacent to the upper surface 155 of the heat spreader 150.

After injecting molding material, a grinding process may be further performed. The encapsulant 170 may surround the substrate 102, the lower semiconductor chip 110, the first upper semiconductor chip 120, the second upper semiconductor chip 130, and the heat spreader 150. The heat spreader 150 may be partially exposed. For example, the upper surface portion 157 of the heat spreader 150 may not be covered by the encapsulant 170. The upper surface of the upper surface portion 157 and the upper surface of the encapsulant 170 may be located at the same level. The encapsulant 170 may cover the recessed portion 156 of the heat spreader 150.

The encapsulant 170 may be a resin including an epoxy or polyimide. For example, the encapsulant 170 may be made of a bisphenol-group epoxy resin, a polycyclic aromatic epoxy resin, an o-cresol novolac epoxy resin, a biphenyl-group epoxy resin or a naphthalene-group epoxy resin.

Referring back to FIG. 2, an external connection terminal 180 may be formed on the lower surface of the substrate 102. The external connection terminal 180 may be connected to the lower pad 106 of the substrate 102 and may be connected to the upper pad 104 through the lower pad 106. After forming the external connection terminal 180, a sorting process may be performed. The substrate 102 may be singulated along a scribe line (not shown) to form the semiconductor packages 100.

FIG. 23 is a vertical cross-sectional view of a semiconductor package according to an example embodiment of inventive concepts.

Referring to FIG. 23, a semiconductor package 1100 may include a lower semiconductor chip 1110, a semiconductor chip stack 1120, and a heat spreader 1150. The semiconductor chip stack 1120 may include a plurality of stacked semiconductor chips. A heat transfer material 1140 may be disposed on the semiconductor chip stack 1120. The heat spreader 1150 may be disposed on the semiconductor chip stack 1120 and may be stacked on the semiconductor chip stack 1120 by the heat transfer material 1140.

A lower end of the heat spreader 1150 may be stacked on a support 1152 disposed on the lower semiconductor chip 1110. For example, the heat spreader 1150 and the support 1152 may be arranged to surround the semiconductor chip stack 1120. The support 1152 may be stacked to the lower semiconductor chip 1110 by an adhesive 1154. The heat spreader 1150 may be stacked to the support 1152 by an adhesive 1156. The encapsulant 170 may completely fill the space surrounded by the heat spreader 1150 and the support 1152. In an example embodiment, the support 1152 may include the same material as the heat spreader 1150. As shown in FIG. 23, the heat spreader 1150 and the support 1152 have a structure connected to the semiconductor chip stack 1120 and the lower semiconductor chip 1110. The heat spreader 1150 and the support 1152 may dissipate heat from the semiconductor chip stack and the lower semiconductor chip 1110.

According to example embodiments of inventive concepts, a heat spreader is in contact with all of a lower semiconductor chip, a first upper semiconductor chip and a second upper semiconductor chip, and thus, heat from the three semiconductor chips may be dissipated to the outside. In addition, since a portion of a upper surface of the heat spreader is exposed, heat from the package may be dissipated more efficiently.

While example embodiments of inventive concepts have been described with reference to the accompanying drawings, it should be understood by those skilled in the art that various modifications may be made without departing from the scope of inventive concepts and without changing essential features thereof. Therefore, the above-described example embodiments should be considered in a descriptive sense only and not for purposes of limitation.

What is claimed is:

1. A semiconductor package comprising:
a lower semiconductor chip on a substrate;
at least one upper semiconductor chip on the lower semiconductor chip;
a heat spreader bonded on the lower semiconductor chip and the at least one upper semiconductor chip, the heat spreader including a first protrusion and a non-protruding portion on a lower surface thereof, the first protrusion being in contact with an upper surface of the lower semiconductor chip and the non-protruding portion being in contact with an upper surface of the at least one upper semiconductor chip; and
an encapsulant surrounding at least the substrate, the lower semiconductor chip, the at least one upper semiconductor chip, and side surfaces of the heat spreader.

2. The semiconductor package of claim 1, further comprising:
heat transfer materials between the lower semiconductor chip and the heat spreader and between the at least one upper semiconductor chip and the heat spreader.

3. The semiconductor package according to claim 1, wherein the encapsulant is configured to partially cover an upper surface of the heat spreader.

4. The semiconductor package according to claim 1, wherein an upper surface of the heat spreader further includes a recessed portion.

5. The semiconductor package of claim 1, wherein the first protrusion is adjacent to the non-protruding portion such that side surfaces of the first protrusion connected to the non-protruding portion are rounded.

6. The semiconductor package according to claim 1, wherein the first protrusion and the at least one upper semiconductor chip are spaced apart by at least 100 μm in a horizontal direction.

7. The semiconductor package of claim 1, wherein the lower semiconductor chip is flip-chip bonded to the substrate.

8. The semiconductor package according to claim 1, further comprising:
an anti-oxidation film on at least the lower surface of the heat spreader.

9. The semiconductor package according to claim 1, wherein an upper surface of the encapsulant adjacent to the heat spreader includes a groove.

10. The semiconductor package according to claim 9, wherein a depth of the groove is 2 μm to 15 μm.

11. The semiconductor package according to claim 1, wherein
the first protrusion and the non-protruding portion are spaced apart in a first horizontal direction, and
the heat spreader extends in a second horizontal direction crossing the first horizontal direction.

12. The semiconductor package of claim 11, wherein, in the second horizontal direction, each of the side surfaces of the heat spreader are vertically aligned with side surfaces of the encapsulant.

13. The semiconductor package of claim 11, wherein the heat spreader further includes a second protrusion in contact with an upper surface of the substrate, the second protrusion protruding more than the first protrusion in a vertical direction.

14. A semiconductor package comprising:
a first lower semiconductor chip and a second lower semiconductor chip in parallel on a substrate;
at least one first upper semiconductor chip on the first lower semiconductor chip;
at least one second upper semiconductor chip on the second lower semiconductor chip;
a first heat spreader bonded on the first lower semiconductor chip and the at least one first upper semiconductor chip, the first heat spreader including a protrusion and a non-protruding portion on a lower surface thereof such that the protrusion is in contact with the first lower semiconductor chip and the non-protruding portion is in contact with the at least one first upper semiconductor chip; and
a encapsulant surrounding at least the substrate, the first lower semiconductor chip, the second lower semiconductor chip, the at least one first upper semiconductor chip, the at least one second upper semiconductor chip, and side surfaces of the first heat spreader.

15. The semiconductor package of claim 14, further comprising:
a second heat spreader in contact with the second lower semiconductor chip and the at least one second upper semiconductor chip.

16. The semiconductor package of claim 14, wherein the first heat spreader is in contact with the second lower semiconductor chip and the at least one second upper semiconductor chip.

17. The semiconductor package of claim 14, wherein the first heat spreader further includes a intermediate non-protruding portion between the first lower semiconductor chip and the second lower semiconductor chip.

18. The semiconductor package according to claim 14, wherein an upper surface of the first heat spreader is partially covered with the encapsulant.

19. A semiconductor package comprising:
a lower semiconductor chip on a substrate;
at least one upper semiconductor chip on the lower semiconductor chip;
a heat spreader bonded on the lower semiconductor chip and the at least one upper semiconductor chip, the heat spreader including a protrusion and a non-protruding portion on a lower surface thereof such that the non-protruding portion is in contact with an upper surface of the at least one upper semiconductor chip;
heat transfer materials connecting the lower semiconductor chip and the at least one upper semiconductor chip to the heat spreader; and
a encapsulant surrounding the substrate, the lower semiconductor chip, the at least one upper semiconductor chip, and side surfaces of the heat spreader such that an upper surface of the heat spreader is partially exposed.

20. The semiconductor package of claim 19, wherein the protrusion is adjacent to the non-protruding portion such that side surfaces of the protrusion connected to the non-protruding portion are rounded.
